(19) United States
(12) Patent Application Publication
(10) Pub. No.: US 2014/0203771 A1
(43) Pub. Date: Jul. 24, 2014

(54) ELECTRONIC PACKAGE, FABRICATION METHOD THEREOF AND ADHESIVE COMPOUND

(71) Applicant: Siliconware Precision Industries Co., Ltd., Taichung (TW)

(72) Inventors: Tsung-Hsien Hsu, Taichung Hsien (TW); Hsin-Lung Chung, Taichung Hsien (TW); Te-Fang Chu, Taichung Hsien (TW); Chia-Yang Chen, Taichung Hsien (TW); Kwok-Yan Lam, Taichung Hsien (TW)

(73) Assignee: Siliconware Precision Industries Co., Ltd., Taichung (TW)

(21) Appl. No.: 13/960,033

(22) Filed: Aug. 6, 2013

(30) Foreign Application Priority Data
Jan. 18, 2013 (TW) 102101935

(51) Int. Cl. H02J 7/02; H05K 3/30; C09J 11/04

(52) U.S. Cl. CPC H02J 7/025; C09J 11/04; H05K 3/30
USPC 320/108; 523/458; 523/459; 29/602.1

(57) ABSTRACT

An electronic package is provided, which includes: a substrate, a charging module and a coil module disposed on the substrate, and an encapsulant formed on the substrate for encapsulating the charging module and the coil module. The coil module has a plurality of coils having an opening, an adhesive compound formed on the coils in a manner that the opening of the coils is exposed from the adhesive compound, and a magnet inserted in the opening of the coils. Further, the adhesive compound comprises a metal oxide. Compared with the conventional ferrite, the adhesive compound is flexible and not easy to crack or break during transportation or assembly, thereby greatly improving the charging efficiency of the electronic package.

### BACKGROUND OF THE INVENTION

1. Field of the Invention

The present invention relates to electronic packages, and more particularly, to a wireless type electronic package, a fabrication method thereof and an adhesive compound used in the package.

2. Description of Related Art

Along with the development of electronic industries, electronic products have a trend towards multi-function and high performance. As portable electronic products such as mobile phones, MP3 players and tablet computers become more popular, charging these portable electronic devices has become increasingly important. An electronic product is usually connected to a charging socket for charging. However, the charging socket in idle is easily covered by a layer of dust, which may adversely affect the charging safety. In addition, a waterproof type electronic product needs a connector to be disposed thereto, thus adversely affecting the sealing structure of the electronic product.

Accordingly, wireless charging technologies are developed to overcome the above-described drawbacks. Generally, a wireless charger has a coil module and a charging module. The coil module consists of copper wire coils, a ferrite and a magnet, and the charging module is disposed on a substrate. The wireless charger charges an electronic device through electromagnetic induction.

FIGS. 1A to 1C are schematic views showing a fabrication method of a conventional wireless charger 1.

Referring to FIG. 1A, a substrate 10 is provided. A charging module 11 and a plurality of coils 120 having an opening are disposed on the substrate 10. The substrate 10 has a contact terminal 100 electrically connected to the charging module 11.

Referring to FIG. 1B, a ferrite 121 is disposed on the coils 120 through an adhesive 123 (shown in FIG. 1C), and the opening of the coils 120 is exposed from the ferrite 121 so as for a magnet 122 to be inserted therein. As such, the magnet 122, the coils 120 and the ferrite 121 form a coil module 12.

Referring to FIG. 1C, an encapsulant 13 is formed on the substrate 10 to encapsulate the charging module 11 and the coil module 12, and the contact terminal 100 is exposed from the encapsulant 13.

However, since the ferrite 121 must be formed into such as a circular shape through molding so as to match the structure of the wireless charger 1, a set of molds of such as different diameters need to be made for each type of the wireless charger 1, thus resulting in a fabrication cost.

Further, since the ferrite 121 has a large thickness and is higher than the charging module 11, the thickness of the encapsulant 13 is correspondingly increased, thus increasing the overall thickness of the wireless charger 1 and hindering miniaturization of the wireless charger 1.

Furthermore, the ferrite 121 is quite crisp and easy to crack or break during transportation or assembly, thereby reducing the charging efficiency of the wireless charger 1.

In addition, the use of the adhesive 123 for attaching the ferrite 121 to the substrate 10 increases the material cost and the fabrication time.

Therefore, how to overcome the above-described drawbacks has become urgent.

### SUMMARY OF THE INVENTION

In view of the above-described drawbacks, the present invention provides an electronic package, which comprises: a substrate; a charging module disposed on the substrate; a coil module disposed on the substrate, wherein the coil module has a plurality of coils having an opening, an adhesive compound formed on the coils in a manner that the opening of the coils is exposed from the adhesive compound, and a magnet inserted in the opening of the coils, the adhesive compound comprising a metal oxide; and an encapsulant formed on the substrate for encapsulating the charging module and the coil module.

The present invention further provides a fabrication method of an electronic package, which comprises the steps of: providing a substrate having a charging module and a plurality of coils disposed thereon, wherein the coils has an opening; forming an adhesive compound on the coils in a manner that the opening of the coils is exposed from the adhesive compound, wherein the adhesive compound comprises a metal oxide; inserting a magnet in the opening of the coils such that the magnet, the coils and the adhesive compound form a coil module; and forming an encapsulant on the substrate for encapsulating the charging module and the coil module.

The method can further comprise curing the adhesive compound.

In the above-describe package and method, the substrate can have a contact terminal electrically connected to the charging module. Further, the contact terminal can be exposed from the encapsulant.

In the above-describe package and method, the metal oxide can be at least one of the group consisting of iron oxide, manganese oxide and zinc oxide, such as Fe₂O₃, Mn₃O₄ and ZnO.

In the above-describe package and method, the adhesive compound can further be formed on the charging module.

The present invention further provides an adhesive compound, which comprises: an epoxy resin; and at least a metal oxide selected from the group consisting of iron oxide, manganese oxide and zinc oxide.

In the above-described adhesive compound, the iron oxide can be Fe₂O₃, the manganese oxide can be Mn₃O₄ and the zinc oxide can be ZnO.

Compared with the conventional ferrite, the adhesive compound of the present invention can be formed into any shape according to the structure of the electronic package. Therefore, the adhesive compound is applicable to any type of the electronic package without the need to make a set of molds for every type of the electronic package as in the prior art, thereby greatly reducing the fabrication cost.

Further, since the adhesive compound has a small thickness, the overall thickness of the electronic package can be reduced to meet the miniaturization requirement of the electronic package.

Furthermore, the adhesive compound is flexible and not easy to crack or break during transportation and assembly, thus greatly improving the charging efficiency of the electronic package.

Moreover, the invention dispenses with the conventional adhesive for attaching a ferrite to a substrate so as to save the material cost, simplify the fabrication process and save the fabrication time and cost.

### BRIEF DESCRIPTION OF DRAWINGS

FIGS. 1A to 1C are schematic upper and cross-sectional views of a conventional wireless charger;

FIGS. 2A to 2D are schematic cross-sectional views showing a fabrication method of an electronic package of the present invention, wherein FIGS. 2A′ to 2C′ are schematic upper views of FIGS. 2A to 2C, respectively; and

FIG. 3 is a schematic upper view showing another embodiment of FIG. 2C′.

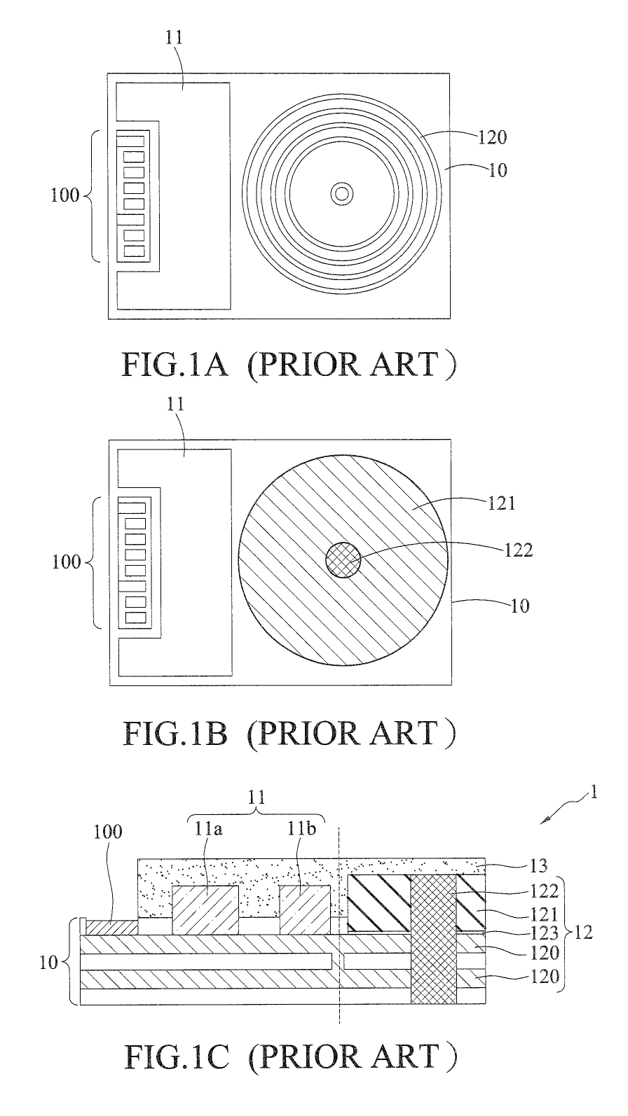

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “a” etc. are merely for illustrative purposes and should not be construed to limit the scope of the present invention.

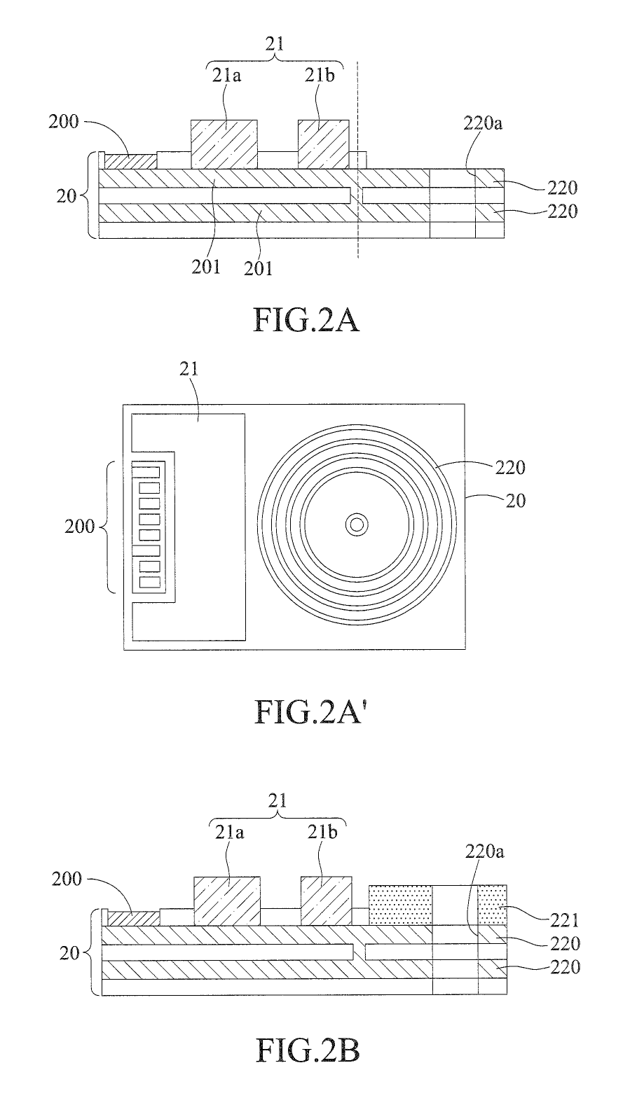

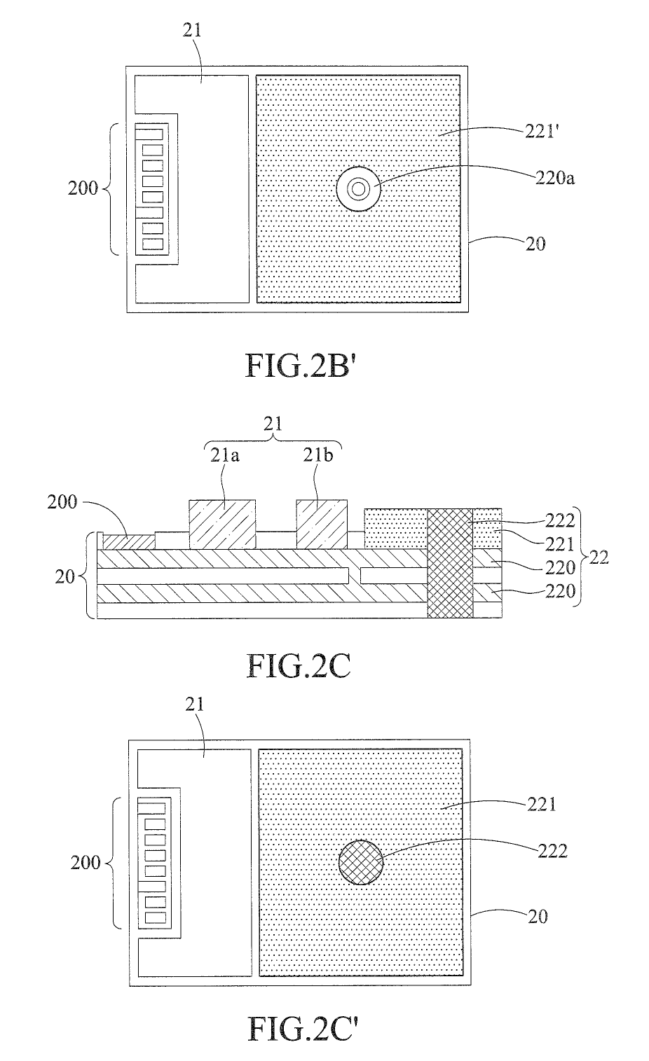

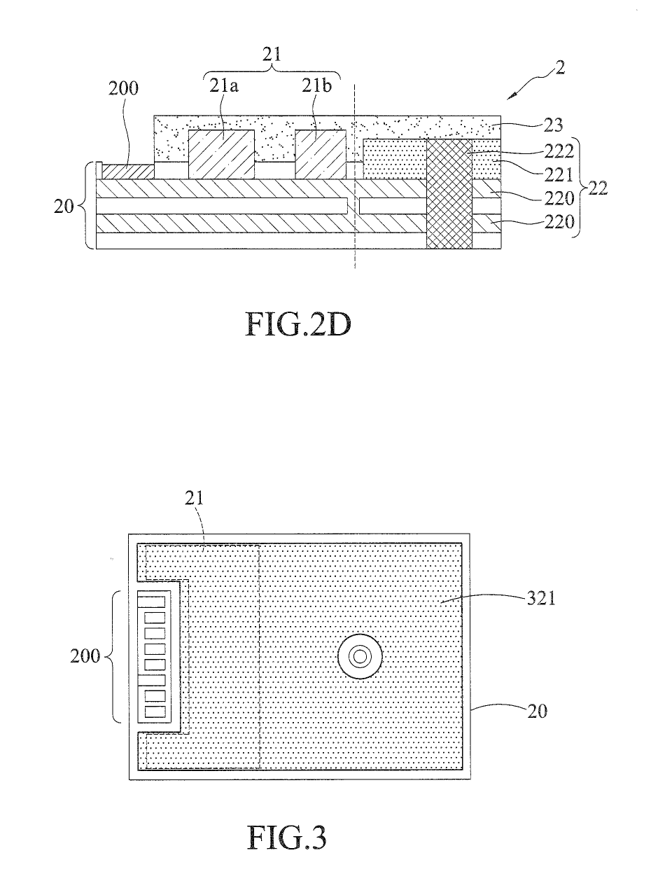

FIGS. 2A to 2D are schematic cross-sectional views showing a fabrication method of an electronic package 2 according to the present invention. The electronic package 2 is a wireless charger.

Referring to FIGS. 2A and 2A′, a substrate 20 is provided, and a charging module 21 and a plurality of coils 220 having an opening 220a are disposed on the substrate 20.

In the present embodiment, the substrate 20 is a circuit board or a ceramic board. The substrate 20 has a contact terminal 200 electrically connected to the charging module 21 and a circuit layer 201 electrically connected to the contact terminal 200.

The charging module 21 has various components. The components are not shown in FIG. 2A′, and in FIG. 2A, only an active element such as a chip 21a and a passive element 21b are shown as examples of the components.

Referring to FIGS. 2B and 2B′, an adhesive compound 221′ is formed on the coils 220 in a manner that the opening 220a of the coils 220 is exposed from the adhesive compound 221′. Therein, the adhesive compound 221′ contains a metal oxide. The adhesive compound 221′ is then cured to form a cured adhesive compound 221.

In the present embodiment, the adhesive compound 221′ is formed by coating or dispensing.

The metal oxide can be iron oxide such as Fe₂O₃. The metal oxide can further contain manganese oxide and zinc oxide such as Mn₃O₄ and ZnO.

In particular, sintered oxides of Mn, Zn and Fe are pulverized and then mixed with an epoxy resin to form an adhesive compound that has a high insulation impedance and high heat dissipating rate and suppresses electromagnetic interferences.

In another embodiment, referring to FIG. 3, an adhesive compound 321 is further formed on the charging module 21.

Referring to FIGS. 2C and 2C′, a magnet 222 is inserted in the opening 220a of the coils 220. As such, the magnet 222, the coils 220 and the adhesive compound 221 form a coil module 22.

Referring to FIG. 2D, an encapsulant 23 is formed on the substrate 210 for encapsulating the charging module 21 and the coil module 22, and the contact terminal 200 is exposed from the encapsulant 23.

Therefore, since the adhesive compound 221, 321 is deformable and can be formed into any shape, such as a circular shape, a rectangular shape or a polygonal shape, according to the structure of the electronic package 2 without the need of a mold, the adhesive compound 221, 321 is applicable to any type of the electronic package 2 without the need to make a set of molds for each type of the electronic package 2 as in the prior art. Therefore, the invention increases the flexibility of design and greatly reduces the fabrication cost and time.

Further, since the adhesive compound 221, 321 has a thickness less than that of the conventional ferrite and is lower than the charging module 21, the thickness of the encapsulant 23 is correspondingly reduced. As such, the overall thickness of the electronic package 2 can be greatly reduced so as to meet the miniaturization requirement of the electronic package 2.

Furthermore, the adhesive compound 221, 321 is flexible and not easy to crack or break during transportation and assembly, thereby greatly improving the charging efficiency of the electronic package 2.

Moreover, the invention dispenses with the conventional adhesive for attaching a ferrite to a substrate, thus saving the material cost, simplifying the fabrication process and saving the fabrication time and cost.

The invention further provides an electronic package 2, which has: a substrate 20, a charging module 21 and a coil module 22 disposed on the substrate 20, and an encapsulant 23 formed on the substrate 20 for encapsulating the charging module 21 and the coil module 22.

The substrate 20 has a contact terminal 200 electrically connected to the charging module 21. Further, the contact terminal 200 is exposed from the encapsulant 23.

The coil module 22 has a plurality of coils 220 having an opening 220a, an adhesive compound 221, 321 formed on the coils 220 in a manner that the opening 220a of the coils 220 is exposed form the adhesive compound 221, 321, and a magnet 222 inserted in the opening 220a of the coils 220.

The invention further provides an adhesive compound 221, 321, which has an epoxy resin and a metal oxide such as iron oxide (Fe₂O₃), manganese oxide (Mn₃O₄) and zinc oxide (ZnO).

In an embodiment, the adhesive compound 321 is further formed on the charging module 21.

Compared with the conventional ferrite, the adhesive compound of the present invention can be formed into any shape according to the structure of the electronic package. Therefore, the adhesive compound is applicable to any type of the electronic package without the need to make a set of molds for every type of the electronic package as in the prior art, thereby greatly reducing the fabrication cost.

Further, since the adhesive compound has a small thickness, the overall thickness of the electronic package can be reduced to meet the miniaturization requirement of the electronic package.

Furthermore, the adhesive compound is flexible and not easy to crack or break during transportation and assembly, thus greatly improving the charging efficiency of the electronic package.

Moreover, the invention dispenses with the conventional adhesive for attaching a ferrite to a substrate so as to save the material cost, simplify the fabrication process and save the fabrication time and cost.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. An electronic package, comprising:
a substrate;
a charging module disposed on the substrate;
a coil module disposed on the substrate, and having coils having an opening, an adhesive compound formed on the coils in a manner that the opening of the coils is exposed from the adhesive compound, and a magnet inserted in the opening of the coils, wherein the adhesive compound comprises a metal oxide; and
an encapsulant formed on the substrate for encapsulating the charging module and the coil module.

2. The package of claim 1, wherein the substrate has contact terminals electrically connected to the charging module.

3. The package of claim 2, wherein the contact terminals are exposed from the encapsulant.

4. The package of claim 1, wherein the metal oxide is at least one selected from the group consisting of iron oxide, manganese oxide and zinc oxide.

5. The package of claim 4, wherein the iron oxide is Fe₂O₃.

6. The package of claim 4, wherein the manganese oxide is Mn₃O₄.

7. The package of claim 4, wherein the zinc oxide is ZnO.

8. The package of claim 1, wherein the adhesive compound is further formed on the charging module.

9. A fabrication method of an electronic package, comprising the steps of:
providing a substrate having a charging module and a plurality of coils disposed thereon, wherein an opening is formed in the coils;
forming an adhesive compound on the coils in a manner that the opening of the coils is exposed from the adhesive compound, wherein the adhesive compound comprises a metal oxide;
inserting a magnet in the opening of the coils such that the magnet, the coils and the adhesive compound form a coil module; and
forming an encapsulant on the substrate for encapsulating the charging module and the coil module.

10. The method of claim 9, wherein the substrate has a contact terminal electrically connected to the charging module.

11. The method of claim 10, wherein the contact terminal is exposed from the encapsulant.

12. The method of claim 9, wherein the metal oxide is at least one selected from the group consisting of iron oxide, manganese oxide and zinc oxide.

13. The method of claim 12, wherein the iron oxide is Fe₂O₃.

14. The method of claim 12, wherein the manganese oxide is Mn₃O₄.

15. The method of claim 12, wherein the zinc oxide is ZnO.

16. The method of claim 9, further comprising forming the adhesive compound on the charging module.

17. The method of claim 9, further comprising curing the adhesive compound.

18. An adhesive compound, comprising:
an epoxy resin; and
at least a metal oxide selected from the group consisting of iron oxide, manganese oxide and zinc oxide.

19. The compound of claim 18, wherein the iron oxide is Fe₂O₃.

20. The compound of claim 18, wherein the manganese oxide is Mn₃O₄.

21. The compound of claim 18, wherein the zinc oxide is ZnO.
